(19) United States
(12) Patent Application Publication
(10) Pub. No.: US 2023/0166981 A1
(43) Pub. Date: Jun. 1, 2023

(54) PIEZOELECTRIC THIN FILM AND METHODS OF FABRICATION THEREOF

(71) Applicants: National University of Singapore, Singapore (SG); Agency for Science, Technology and Research, Singapore (SG)

(72) Inventors: Moaz WAQAR, Singapore (SG); John WANG, Singapore (SG); Stephen John PENNYCOOK, Singapore (SG); Haijun WU, Singapore (SG); Kui YAO, Singapore (SG); Huajun LIU, Singapore (SG)

(21) Appl. No.: 17/920,738

(22) PCT Filed: Apr. 16, 2021
(86) PCT No.: PCT/SG2021/050218

§ 371 Date: Oct. 21, 2022

(30) Foreign Application Priority Data
Apr. 24, 2020 (SG) 10202003767Q

(51) Int. Cl. C01G 33/00; H10N 30/00; H10N 30/853; H10N 30/076

(52) U.S. Cl. CPC C01G 33/006; H10N 30/10516; H10N 30/8542; H10N 30/076; C01P 2006/40; C01P 2002/78; C01P 2002/60; C01P 2002/77; C01P 2004/04

(57) ABSTRACT

The present invention relates, in general terms, to piezoelectric thin films with an empirical formula (K₁ₓNaₓ)_{y}NbO₃, wherein 0≤x≤1 and 0.64≤y≤0.95. In particular, the piezoelectric thin film comprises at least two adjacent NbO₂ planes in an antiphase boundary, the at least two adjacent NbO₂ planes displaced from each other by about half a lattice length in either the (100), (010) or (100) crystallographic plane. The present invention also relates to methods of fabricating the piezoelectric thin films.

### TECHNICAL FIELD

The present invention relates, in general terms, to piezoelectric thin films. The present invention also relates to methods of fabricating the piezoelectric thin films.

### BACKGROUND

A piezoelectric material is a material which can convert mechanical energy into electrical energy and vice versa. Piezoelectric materials can be utilized to perform various desired functions. They are widely used as actuators where the piezoelectric element deforms with the application of electric field and as sensors where any physical quantity can be indirectly detected by utilizing the voltage generated in the piezoelectric element due to deformation.

A piezoelectric thin film is a very fine lamellae of piezoelectric material. The piezoelectric thin film is attached to a substrate and has numerous practical applications. A few conventional applications of a piezoelectric thin film include ultrasonic transducers, micro-pumps, micro-cantilever based mass sensors, inkjet printer heads, gyroscopes and accelerometers. Piezoelectric thin films can easily be integrated into micro-electromechanical systems (MEMS). For specific applications, such as a fuel injectors, micro-langevin transducers and nanocontrol systems for optical cavities etc., a high effective longitudinal piezoelectric coefficient (d₃₃*) is required to obtain a large piezoelectric, piston-like deformation in piezoelectric thin film actuators.

The most widely used piezoelectric material is a lead-based perovskite ferroelectric and commonly referred to as PZT having chemical formula, PbZr₁₋ₓTiₓO₃, 0<x<1. PZT has superior piezoelectric properties at x=0.48 as two different crystal structures, namely rhombohedral and tetragonal phases, exist at the same time also known as morphotropic phase boundary (MPB).

However, the use of lead-based piezoelectric materials had raised environmental concerns, and accordingly, there is strong demand for lead-free piezoelectric materials due to the concerns over lead contamination. Several lead-free piezoelectric materials are under investigation, among which alkali niobate based ceramic system, commonly expressed with a general formula K₁₋ₓNaₓNbO₃, 0<x<1, exhibits relatively good piezoelectric properties among the systems being tested. However, the piezoelectric properties are still not on par with lead-based piezoelectric materials. In this regard, a lot of attention has been paid to enhance d₃₃* of alkali niobate based piezoelectric ceramics. Recent achievements in this direction include attaining a d₃₃* up to 250 pm/V in a 2.7 pm thick piezoelectric film having phase co-existence and a complex composition of 0.95(K_{0.48}Na_{0.52})(Nb_{0.95}Sb_{0.05})O_{3-0.05}Bi_{0.5}(Na_{0.82}K_{0.18})_{0.5}ZrO₃ made via a modified sol-gel method. However, for practical applications, such complex composition can be challenging to fabricate on a large scale as precise control is required and the piezoelectric properties still need to be improved to compete with the lead-based piezoelectric materials.

With the progress in technology, downsizing and higher performance are desired for functional components comprising of piezoelectric materials used in electronic devices. Research efforts and industrial developments have been made to reduce the thickness of piezoelectric materials in the form of piezoelectric thin films which are used in various applications. Sputtering, on the other hand, has been utilized to make alkali niobate based thin film actuator on Si substrate. However, in general, piezoelectric properties of alkali niobate based thin films remain far behind those of PZT. For example, the piezoelectric coefficient can be improved in piezoelectric thin film with general formula (NaₓK_{y}Li_{z})NbO₃, (0≤x≤1, 0≤y≤1, 0≤z≤0.2, x+y+z=1) by adding crystal texture to the film constituted of particles with columnar structure provided that the angle between the columnar grain axis and normal line to the substrate surface be in the range of 0° to 10°.

However, the piezoelectric properties of lead-free alkali niobate based thin films are still not comparable with lead-based piezoelectric thin films after such tremendous efforts. Another strategy is to obtain piezoelectric thin films with complex composition, such as with chemical formula (KₓNa₁₋ₓ)_{1-y}A_{y}Nb_{1-z}B_{z}O₃, where A=Li, Bi, Ba and B=Sb, Ta, Zr, Hf, 0<x<1, 0<y≤0.06, 0<z≤0.1, which show significantly improved piezoelectric properties. Such a piezoelectric thin film can be produced by a chemical solution method in which an amorphous thin film is deposited on the substrate and then this structure including the substrate is subjected to a high temperature to facilitate the crystallographic growth. This process is repeated in many cycles until the desired thickness of thin film is obtained. It is challenging to control the processing, composition and thus performance consistency in mass production of such piezoelectric thin films derived from chemical solution with complex composition.

A piezoelectric thin film is generally made on a Si or MgO substrate buffered with a thin layer of Pt. A (111) oriented Pt layer having a thickness of not more than 200 nm is made on an oxidized Si substrate to get an alkali niobate based piezoelectric polycrystalline thin films with grains preferentially oriented in [001] crystal direction. Alternatively, a perovskite oxide layer such as LaNiO₃ can also be made on top of the Pt layer to get similar or better results. However, such a piezoelectric thin film is not absolutely oriented in (001) direction and might just have 80-90% orientation in (001) direction. Moreover, it is very difficult to avoid pyrochlore phase in alkali niobate based piezoelectric thin films as the alkali metals evaporate during the heat treatment of piezoelectric layer.

It would be desirable to overcome or ameliorate at least one of the above-described problems, or at least to provide a useful alternative.

### SUMMARY

The present invention is based on the discovery that a large longitudinal piezoelectric coefficient can be obtained in an alkali niobate based piezoelectric epitaxial thin film with a formula (K,Na)NbO₃ grown on a (001) oriented single crystal substrate such that (K+Na)/Nb ratio is from about 0.64 to about 0.95. And by the virtue of which the thin film consists of columnar grains perpendicular to the film surface and separated by antiphase boundaries, density of which can be controlled by controlling (K+Na)/Nb ratio in the said thin film.

The present invention provides a piezoelectric thin film element comprising:
a) a piezoelectric thin film, the piezoelectric thin film with an empirical formula (K₁₋ₓNaₓ)_{y}NbO₃, wherein 0≤x≤1 and 0.64≤y≤0.95; and
b) a single crystal substrate having a (001), (010) or (100) crystallographic plane perpendicular to a surface;

wherein the piezoelectric thin film is adjacent to the surface of the single crystal substrate and the piezoelectric thin film is oriented such that its (001), (010) or (100) crystallographic plane is substantially parallel to either the (001), (010) or (100) crystallographic plane of the single crystal substrate; and

wherein the piezoelectric thin film comprises at least two adjacent NbO₂ planes in an antiphase boundary, the at least two adjacent NbO₂ planes displaced from each other by about half a lattice length in either the (100), (010) or (100) crystallographic plane.

Advantageously, having a (K+Na)/Nb ratio of more than or equal to 0.64 and less than or equal to 0.95 in the piezoelectric thin film grown on a, for example, (001) oriented single crystal substrate results in the formation of imperfect grain boundaries where a NaO/KO plane is missing and two adjacent NbO₂ planes are arranged antiphase to each other (antiphase boundary). Advantageously, this allows for an increase in effective longitudinal piezoelectric coefficient (d₃₃*) of at least 1000 pm/V.

In some embodiments, the piezoelectric thin film has columnar grains oriented in a respective [001], [010] or [100] direction.

In some embodiments, the at least two adjacent NbO₂ planes in the antiphase boundary are displaced from each other by about 0.220 nm to about 0.260 nm in the (100), (010) or (100) crystallographic plane.

In some embodiments, density of antiphase boundaries of the piezoelectric thin film is about 0.05 nm⁻¹ to about 0.30 nm⁻¹.

In some embodiments, the piezoelectric thin film has an effective longitudinal piezoelectric coefficient (d₃₃*) of about 1200 pm/V to about 1700 pm/V at an applied voltage of about 60 kV/cm and a frequency of about 1 kHz.

In some embodiments, the piezoelectric thin film has a columnar structure, the columnar structure having a width of about 3 nm to about 6 nm.

In some embodiments, the piezoelectric thin film has a thickness of about 100 nm to about 500 nm.

In some embodiments, the substrate is an optionally doped perovskite single crystal.

In some embodiments, the substrate is a perovskite single crystal selected from SrTiO₃, LaAlO₃, DyScO₃, (La,Sr)(Al,Ti)O₃, Si, NdGaO₃, LiTaO₃, YAlO₃, LaₓSr₁₋ₓFeO₃, LaₓCa₁₋ₓFeO₃, LaₓSr₁₋ₓCoO₃, LaₓSr₁₋ₓMnO₃, LaNiO₃, and SrRuO₃.

In some embodiments, the piezoelectric thin film element further comprises a perovskite oxide layer sandwiched between the piezoelectric thin film and the substrate.

In some embodiments, the perovskite oxide layer is selected from LaₓSr₁₋ₓFeO₃, LaₓCa₁₋ₓFeO₃, LaₓSr₁₋ₓCoO₃, LaₓSr₁₋ₓMnO₃, LaNiO₃, and SrRuO₃.

In some embodiments, the perovskite oxide layer has a thickness of about 1 nm to about 300 nm.

In some embodiments, the piezoelectric thin film element further comprises an electrode layered on top of the piezoelectric thin film.

In some embodiments, the electrode is selected from Pt, Au, Ag, Cu, Cr, Al, LaₓSr₁₋ₓFeO₃, LaₓCa₁₋ₓFeO₃, LaₓSr₁₋ₓCoO₃, LaₓSr₁₋ₓMnO₃, LaNiO₃, and SrRuO₃.

The present invention also provides a piezoelectric device, comprising
a) piezoelectric thin film element as disclosed herein; and
b) at least two electrodes in contact with the piezoelectric thin film.

In some embodiments, the single crystal substrate in the piezoelectric device is one of the at least two electrodes.

The present invention also provides a method of fabricating a piezoelectric thin film element, comprising:
forming a piezoelectric thin film with an empirical formula (K₁₋ₓNaₓ)_{y}NbO₃ on a single crystal substrate, wherein 0≤x≤1 and 0.64≤y≤0.95;
wherein the single crystal substrate has a (001), (010) or (100) crystallographic plane perpendicular to a surface; and
wherein the piezoelectric thin film is adjacent to the surface of the single crystal substrate and the piezoelectric thin film is oriented such that its (001), (010) or (100) crystallographic plane is substantially parallel to either (001), (010) or (100) crystallographic plane of the single crystal substrate; and
wherein the piezoelectric thin film comprises at least two adjacent NbO₂ planes in an antiphase boundary, the at least two adjacent NbO₂ planes displaced from each other by about half a lattice length in either the (100), (010) or (100) crystallographic plane.

In some embodiments, the step of forming the piezoelectric thin film comprises depositing the piezoelectric thin film using sputtering.

In some embodiments, the step of forming the piezoelectric thin film comprises sputtering at a substrate temperature of about 680° C. and a discharge power of about 120 W.

In some embodiments, the sputtering is performed for at least 2 h.

In some embodiments, the sputtering is performed in an argon-oxygen ratio (Ar/O) of about 50/15.

In some embodiments, the sputtering is performed under a total pressure of about 3.5×10⁻³ mtorr.

In some embodiments, the sputtering angle, substrate-target distance, argon-oxygen ratio and/or deposition temperature are controlled such that y is 0.64≤y≤0.95.

In some embodiments, the perpendicular distance between the target and substrate is from about 5 cm to 15 cm.

In some embodiments, the angle between the target normal and substrate normal is an obtuse angle.

In some embodiments, the method further comprises a step of cutting and polishing a surface of the single crystal substrate having a (001), (010) or (100) crystallographic plane perpendicular to the surface before the sputtering.

### BRIEF DESCRIPTION OF THE DRAWINGS

Embodiments of the present invention will now be described, by way of non-limiting example, with reference to the drawings in which:

FIG. 1 illustrates a schematic diagram showing a perovskite unit cell of (K,Na)NbO₃;

FIG. 2 illustrates a schematic diagram showing a regular perfect boundary 1 and an antiphase boundary 2 with NbO₂ plane shifted by ½a<100> distance;

FIG. 3 illustrates a structural diagram showing the piezoelectric thin film element (piezoelectric thin film 4 made on a conductive single crystal substrate 3);

FIG. 4 illustrates a structural diagram showing a conductive perovskite layer 6 between the piezoelectric thin film 4 and an insulative single crystal substrate 5;

FIG. 5 illustrates a structural diagram showing a top electrode 7 on a piezoelectric thin film 4 made on a conductive single crystal substrate 3;

FIG. 6 illustrates a structural diagram showing a top electrode 7 on a piezoelectric thin film 4 with a conductive perovskite layer 6 beneath and an insulative single crystal substrate 5;

FIG. 7 illustrates a bright field scanning transmission electron micrograph of an exemplary piezoelectric thin film cross-section showing a 300 nm thick piezoelectric thin film 9 on a conductive 0.5% Nb doped SrTiO₃ single crystal substrate 8 according to Example 1;

FIG. 8 illustrates a high angle annular dark field scanning transmission electron micrograph of piezoelectric thin film surface showing fine grains separated by niobium rich antiphase boundaries as according to Example 1 (only Nb atoms are visible in the micrograph);

FIG. 9 illustrates a magnified high angle annular dark field scanning transmission electron micrograph of an antiphase boundary enclosed within the rectangle (only Nb atoms are visible in the micrograph);

FIG. 10 illustrates an exemplary piezoelectric response of the piezoelectric thin film on the application of a sine wave electric signal at a frequency of 1 kHz according to Example 1;

FIG. 11 illustrates an exemplary bright field scanning transmission electron micrograph of piezoelectric thin film cross-section showing a 300 nm thick piezoelectric thin film on a conductive 0.5% Nb doped SrTiO₃ single crystal substrate according to Example 2; and

FIG. 12 illustrates an exemplary piezoelectric response of the piezoelectric thin film on the application of a sine wave electric signal at a frequency of 1 kHz according to Example 2.

### DETAILED DESCRIPTION

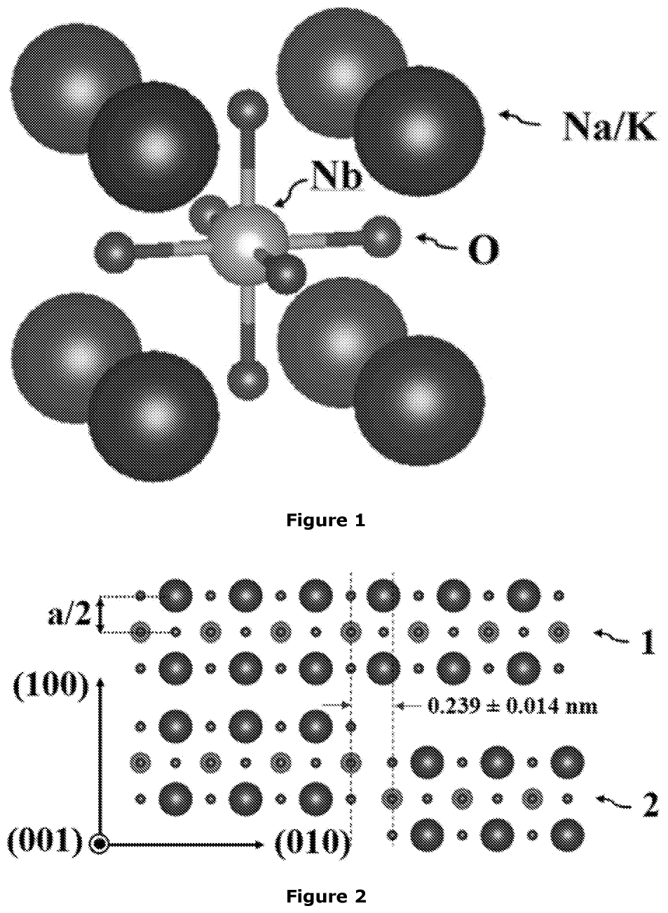

The present invention is based on potassium sodium niobate with a general formula K₁₋ₓNaₓNbO₃, 0<x<1 (also referred to as KNN). KNN is a lead-free piezoelectric ceramic system with a perovskite structure. In the form of a piezoelectric thin film, it exists in an orthorhombic or a tetragonal structure with Potassium (K) or Sodium (Na) at A-site (vertex site of the crystal lattice), Niobium (Nb) at B-site (a body centered site of the crystal lattice) and Oxygen (O) making an octahedron around Nb (See FIG. 1).

The inventors had reviewed past work and have found that the piezoelectric property of alkali niobate thin film can be improved by specifically tuning the ratio of the alkali metal to Nb and controlling its crystallographic growth.

In this regard, a prior art piezoelectric thin film with general formula (K₁₋ₓNaₓ)_{y}NbO₃ shows piezoelectric properties with typical d₃₃ below 180 pm/V (considering d₃₁ is typically around −d₃₃/2) when 0.4≤x≤0.7 and y is close to 1. In another example, polycrystalline alkali niobate based thin film with general formula (K₁₋ₓNaₓ)_{y}NbO₃, where 0.4≤x≤0.7 and 0.75≤y≤0.90, grown on a Pt buffered Si substrate can improve the piezoelectric coefficient i.e. up to d₃₃=218 pm/V. In another example, a piezoelectric film with general formula (K₁₋ₓ Naₓ)NbO₃, (0<x<1) shows piezoelectric properties if (001) crystallographic peak occupies 80% or more of the diffraction pattern.

Accordingly, the present invention is predicated on the understanding that as opposed to a polycrystalline thin film, a single crystal film grows by the virtue of perfect atomic arrangement determined by the termination species of the substrate surface. For example, in the island growth mode of KNN thin films with (K+Na)/Nb ratio close to 1, different grains nucleate from the surface of the substrate and join together with continuous grain boundaries [see 1 in FIG. 2]. It was found that when the (K+Na)/Nb ratio is smaller than 1 in a KNN piezoelectric thin film grown on, for example, 001 oriented single crystal substrate, some grains show atypical nucleation and result in the formation of imperfect grain boundaries when grown on a single crystal substrate where a NaO/KO plane is missing. In particular, two adjacent NbO₂ planes can be arranged antiphase to each other [see 2 in FIG. 2]. The arrangement of this antiphase boundary is such that one of the adjacent NbO₂ layers is displaced by a distance of half a lattice length in the horizontal direction (½<100> a or ½<010> a) and the distance between the NbO₂ planes is in the range of 0.225-0.252 nm.

Based on this understanding, the inventors have found that in general, a KNN based piezoelectric thin film with a general formula of (K₁₋ₓNaₓ)NbO₃, having (K+Na)/Nb ratio smaller than 1, in (K₁₋ₓNaₓ)NbO₃ thin film (0≤x≤1) can result in the formation of aforementioned antiphase boundaries when grown on a single crystal substrate. In particular, (K+Na)/Nb ratio can be from about 0.64 to about 0.95. Furthermore, such thin film with antiphase boundaries can show huge d₃₃* up to 1621.9 pm/V measured at applied voltage and frequency of 58.3 kV/cm and 1 kHz respectively. The density of antiphase boundaries (number of antiphase boundaries per unit length of crystal lattice) increases with the decrease in the value of (K+Na)/Nb ratio such that the density of antiphase boundaries ranges from 0.08 to 0.23 nm⁻¹ when (K+Na)/Nb ratio lies between 0.95 to 0.64 respectively. Furthermore, the d₃₃* of 1621.9 pm/V is achievable in a thin film with antiphase boundary density of 0.23 nm⁻¹ and (K+Na)/Nb ratio equal to 0.64. Hence, the d₃₃* of alkali niobate thin films can be controlled by adjusting the amount of Nb content in the films with respect to the alkali metals K and Na when grown on a single crystal substrate. Additionally, the thickness of films of the present invention (about 300 nm) could be much thinner than the films disclosed in the previous inventions.

For the avoidance of doubt, as used herein, ‘piezoelectric thin film element’ refers to a piezoelectric thin film in combination with a substrate. ‘Piezoelectric thin film’ refers to only the film portion; i.e. without the substrate.

A substrate is generally required to grow a piezoelectric thin film. While substrate is a support for thin film during the growth process, the substrate can also be an essential component to impart the desired structure to the thin film during growth. The inventors have found and as presented in some embodiments, a [001] oriented substrate can be used to obtain a piezoelectric thin film with high d₃₃. In other embodiments, [010] or [100] oriented substrates can also be used. It should be noted that, in the form of a final end product, the piezoelectric thin film can be utilized without a substrate; i.e. the substrate can be removed after formation of the piezoelectric thin film. For example, water-soluble single crystal substrate and/or organic single crystal substrate can be used.

In some embodiments, the piezoelectric thin film element consists of a piezoelectric thin film and a substrate. The substrate can be a conductive single crystal with perovskite structure such as 0.5% Nb-doped SrTiO₃. The substrate is cut and polished perpendicular to one of the primary crystallographic axes, for example (001). A piezoelectric thin film made on top of the substrate. The piezoelectric thin film has a general formula (K,Na)NbO₃ and (K+Na)/Nb ratio from about 0.64 to about 0.95 and having a preferential orientation in, for example, [001] crystallographic direction with columnar grains oriented parallel to the normal of the film surface. These columnar grains are separated from each other via antiphase boundaries (APBs) such that the density of antiphase boundaries lies between 0.08 to 0.23 nm⁻¹ when (K+Na)/Nb ratio lies between 0.95 to 0.64 respectively. The APBs are such that a layer of KO or NaO is missing in the regular perovskite structure, and that the two NbO₂ layers are adjacent to each other at antiphase boundaries. Furthermore, one of these adjacent NbO₂ layers is displaced from its otherwise normal position by ½ a<100> or ½ a<010> distance where ‘a’ is the lattice parameter of perovskite cell in the horizontal direction.

Other crystallographic axes can also be used. For example, (001), (010) and (100) crystallographic axis of the substrate can be used, which results in the corresponding piezoelectric thin film having either (001), (010) or (100) crystallographic direction with columnar grains oriented parallel to the normal of the film surface.

As used herein, round brackets such as ‘(001)’ are used to denote a crystallographic plane, while square brackets such as ‘[001]’ are used to denote a crystallographic direction.

The empirical formula of a chemical is a simple expression of the relative number of each type of atom or ratio of the elements in the compound. Empirical formulae are the standard for ionic compounds, such as CaCl₂), and for macromolecules, such as SiO₂. An empirical formula makes no reference to isomerism, structure, or absolute number of atoms. The term empirical refers to the process of elemental analysis, a technique of analytical chemistry used to determine the relative percent composition of a pure chemical substance by element. For example, hexane has a molecular formula of C₆H₁₄, or structurally CH₃CH₂CH₂CH₂CH₂CH₃, implying that it has a chain structure of 6 carbon atoms, and 14 hydrogen atoms. However, the empirical formula for hexane is C₃H₇. Likewise, the empirical formula for hydrogen peroxide, H₂O₂, is simply HO expressing the 1:1 ratio of component elements. Formaldehyde and acetic acid have the same empirical formula, CH₂O. This is the actual chemical formula for formaldehyde, but acetic acid has double the number of atoms.

The present invention predicated on the piezoelectric thin film being grown on a single crystal substrate having a (001), (010) or (100) orientation parallel to the growth direction of the thin film. 100% orientation in, for example, [001] crystal direction is achieved in alkali based piezoelectric thin film by using a single crystal substrate. In this regard, the piezoelectric thin film is completely or at least substantially oriented in the [001] direction and/or the (001) plane. Furthermore, the piezoelectric thin film can be free from secondary pyrochlore phase. To achieve this, the lattice parameters in the horizontal plane of the substrate are preferably close to (or matched with) the lattice parameters in the horizontal plane of the piezoelectric thin film.

In some embodiments, the piezoelectric thin film has an effective longitudinal piezoelectric coefficient d₃₃* of 1621.9 pm/V at an applied voltage and frequency of 58.3 kV/cm and 1 kHz respectively. This exceeds that of the commercially available lead-based piezoelectric thin films. Further, the piezoelectric thin film is void of other foreign elements which would otherwise be necessary to enhance the piezoelectric properties to such extent. Furthermore, the piezoelectric thin film is made using a sputtering process.

As mentioned, an effective longitudinal piezoelectric coefficient d₃₃* of 1621.9 pm/V at a driving voltage of 58.3 kV/cm and at 1 kHz frequency can be obtained using the piezoelectric thin film of the present invention. Advantageously, this is a higher longitudinal piezoelectric response than existing lead-based and lead-free piezoelectric thin films. This also opens up possibilities of developing more sensitive and energy efficient lead-free electromechanical devices.

Further, by growing the thin films on a single crystal substrate, a high density of antiphase boundaries can result in giant d₃₃* in alkali niobate thin films. Antiphase boundaries can be produced, the density of which can be controlled by adjusting the Niobium content in the film with respect to the alkali metals. In such case, Nb content in the sputtering target directly effects the amount of Nb in the film. Advantageously, d₃₃* of piezoelectric thin films can be drastically increased simply by adjusting the stoichiometry of target composition in sputtering as compared to the conventional method of creating phase boundaries by adding expensive dopants. This simple method offers advantage of improved reproducibility and thus provides opportunity for mass scale production.

Advantageously, the piezoelectric thin film, piezoelectric thin film element and/or device is compliant with Restriction of Hazardous Substances (RoHS), which currently restricts the use of lead in consumer products. The current workaround has been to exempt PZT for the time being from RoHS considerations for use in electronic products because of the unavailability of suitable alternative. This invention could potentially lead to a lead-free piezoelectric material to replace PZT in a number of devices and applications.

Advantageously, the higher d₃₃* renders piezoelectric thin film actuators to be driven at very low voltage hence facilitating further miniaturization and broaden its applications. The high d₃₃* of 1621.9 pm/V is significantly higher than the lead-based counterparts commercially used for practical applications. Additionally, such a high piezoelectric constant is achieved without the addition of complex dopants and the piezoelectric thin film is prepared by a simple sputtering process.

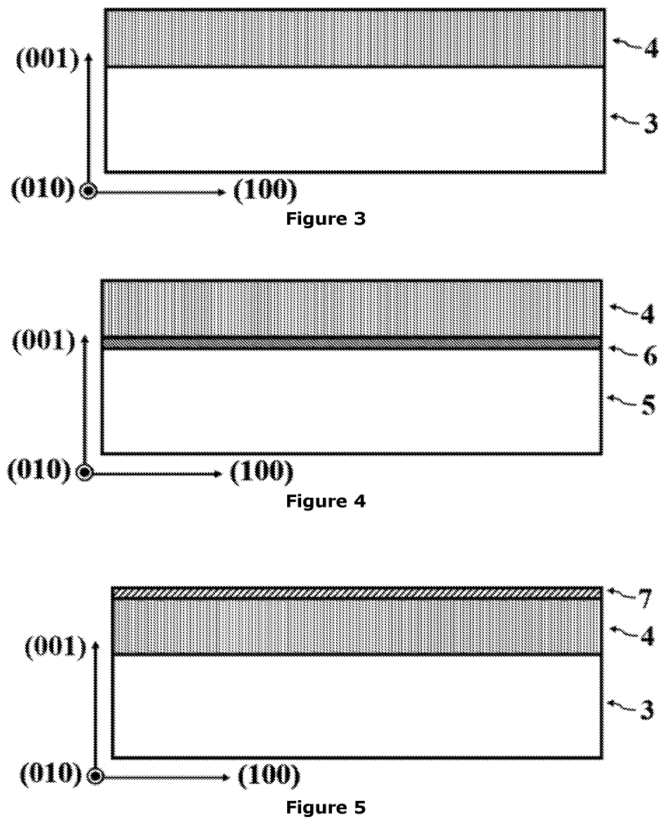

A typical sensor or actuator device based on a piezoelectric thin film has at least two electrodes to attach a voltmeter to measure the bias or to attach a voltage source for driving actuation respectively. In some embodiments, the substrate can be conductive and can act as one of the electrodes (See 3 in FIG. 3). For example, one of these electrodes can be a conductive substrate which was used for the growth process i.e. in the piezoelectric thin film element. In some embodiments, a Nb doped SrTiO₃ conductive substrate was used. In this Nb doped substrate, Nb can make SrTiO₃ conductive (SrTiO₃ is an insulator). In other embodiments, an intrinsically conductive substrate can also be used.

An insulating perovskite single crystal 5 from a group including but not limited to SrTiO₃, LaAlO₃, DyScO₃, (La,Sr)(Al,Ti)O₃, Si, NdGaO₃, LiTaO₃, YAlO₃ may also be used (See FIG. 4). The inventors have found that the piezoelectric thin film of the present invention can be made using an insulative substrate. However, it was found that its applicability as a device can be limited. Accordingly, to solve this, the inventors have found that a conductive perovskite layer can be positioned between the piezoelectric thin film and the substrate. This conductive layer can thus act as the bottom electrode for use as a device. In such case, a conductive layer of a conductive perovskite 6 preferably a metal oxide from a group including, but not limited to, LaₓSr₁₋ₓFeO₃, LaₓCa₁₋ₓFeO₃, LaₓSr₁₋ₓCoO₃, LaₓSr₁₋ₓMnO₃, LaNiO₃, SrRuO₃ is made on the top of the aforementioned insulating substrate (See FIG. 4). Typically, the thickness of the conductive electrode is between 1-250 nm.

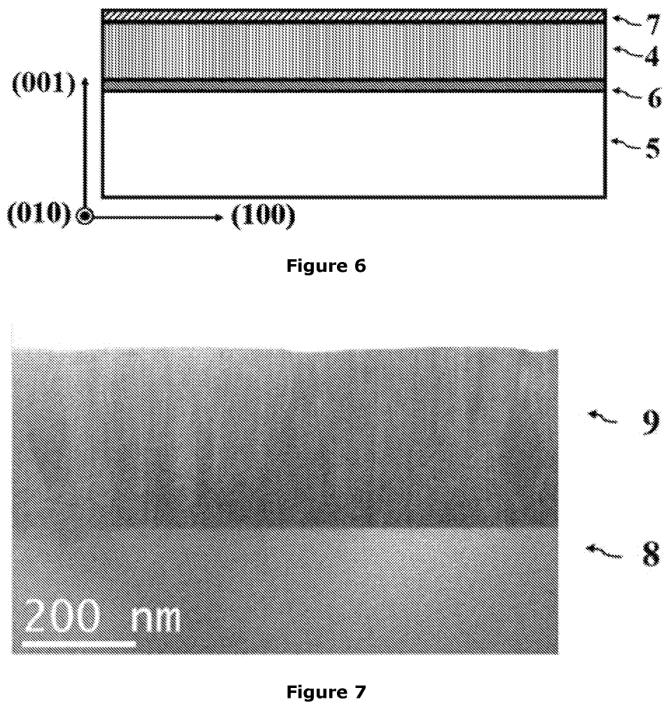

An electrode 7 can be deposited on the top surface of the piezoelectric thin film (see FIGS. 5 and 6). This top electrode is preferably a metal such as, but not limited, to Pt, Au, Ag, Cu, Cr, Al or a conductive perovskite as listed previously. The top layer is preferably deposited by using sputtering or vapour deposition method, or plating method, or paste method.

A method of fabricating piezoelectric thin films with general formula (K,Na)NbO₃ and (K+Na)/Nb ratio from about 0.64 to about 0.95, is also disclosed herein. For the embodiments of this invention discussed below, substrate is a 5 mm×5 mm×0.5 mm, 0.5% Nb doped SrTiO₃ conductive perovskite single crystal cut and polished perpendicular to the (001) crystal plane. Formed directly on it is the piezoelectric thin film by rf magnetron sputtering at substrate temperature of 680° C. and the discharge power used is 120 W. Other conditions are: chamber gas is Ar/O=50/15 at a total pressure of 3.5×10⁻³ mtorr, sputtering duration of 2 hours. Additionally, 200 μm diameter Pt electrodes with thickness of 100 nm may be deposited at room temperature using a mask at a sputtering power of 80 W and a duration of 10 minutes. For (K,Na)NbO₃ thin films, (K+Na)/Nb ratio can be controlled by adjusting Nb content in the sputtering target. For (K+Na)/Nb ratio smaller than 1, excess Nb may be added to the sputtering target as compared to a stoichiometric target when (K+Na)/Nb ratio is 1. Similarly, (K+Na)/Nb can also be controlled by adjusting the sputtering angle, substrate-target distance, argon-oxygen ratio and/or deposition temperature.

Accordingly, the present invention provides a piezoelectric thin film element comprising:
a) a piezoelectric thin film with formula (K,Na)NbO₃ and said film having (K+Na)/Nb ratio from about 0.64 to about 0.95; and
b) a single crystal substrate having a (001), (010) or (100) crystallographic plane perpendicular to a surface;

wherein the piezoelectric thin film is adjacent to the surface of the single crystal substrate and the piezoelectric thin film is oriented such that its (001), (010) or (100) crystallographic plane is parallel to either (001), (010) or (100) crystallographic plane of the single crystal substrate.

In this regard, the piezoelectric thin film is oriented such that its (001) crystallographic plane is parallel to either (001), (010) or (100) crystallographic plane of the single crystal substrate. The piezoelectric thin film can also be oriented such that its (010) crystallographic plane is parallel to either (001), (010) or (100) crystallographic plane of the single crystal substrate. The piezoelectric thin film can also be oriented such that its (100) crystallographic plane is parallel to either (001), (010) or (100) crystallographic plane of the single crystal substrate.

It should be appreciated that as long as the ‘atomic spacing information’ from the crystallographic plane can be imparted from the substrate to the formed piezoelectric thin film, the piezoelectric thin film does not have to be in physical and/or chemical contact with the substrate. In this regard, the piezoelectric thin film being adjacent to the surface of the single crystal substrate is in close proximity with the surface of the single crystal substrate. This means that that the piezoelectric thin film can either be in physical and/or chemical contact/connected (no intervening structure between them) with the surface of the single crystal substrate or spaced apart/separated from the surface of the single crystal substrate by a small distance/space (by way of an intervening structure between them). Thus ‘information’ is relayed directly from the substrate allows for the formation of a piezoelectric thin film which is in physical and/or chemical contact with the substrate. This means that when the piezoelectric thin film is grown on the substrate, the single crystal substrate has a perfect atomic alignment with the piezoelectric thin film, and these atoms are chemically bonded to each other. When ‘information’ is relayed indirectly by way of the intervening structure, the ‘information’ from the substrate is transmitted and contained in the intervening structure, which is then transmitted to the formed piezoelectric thin film. For example, the intervening structure can be an electrically conductive thin film grown on the substrate which has the same (or substantially the same) crystallographic plane orientation as the substrate. To this end, the intervening structure can be crystallographically similar to the substrate (single crystalline with same orientation), such that the intervening structure is chemically bonded to both thin film and the substrate, but might have different physical properties (such as electrical conductivity).

In some embodiments, the present invention provides a piezoelectric thin film element comprising:
a) a piezoelectric thin film with formula (K,Na)NbO₃ and said film having (K+Na)/Nb ratio from about 0.64 to about 0.95; and
b) a single crystal substrate having a (001), (010) or (100) crystallographic plane perpendicular to a surface;

wherein the piezoelectric thin film is adjacent to the surface of the single crystal substrate and the piezoelectric thin film is oriented such that its (001), (010) or (100) crystallographic plane is parallel to the respective (001), (010) or (100) crystallographic plane of the single crystal substrate.

In some embodiments, if the single crystal substrate has a (001) crystallographic plane perpendicular to a surface, the piezoelectric thin film is oriented such that its (001) crystallographic plane is parallel to the (001) crystallographic plane of the single crystal substrate. In other embodiments, if the single crystal substrate has a (010) crystallographic plane perpendicular to a surface, the piezoelectric thin film is oriented such that its (010) crystallographic plane is parallel to the (010) crystallographic plane of the single crystal substrate. In other embodiments, if the single crystal substrate has a (100) crystallographic plane perpendicular to a surface, the piezoelectric thin film is oriented such that its (100) crystallographic plane is parallel to the (100) crystallographic plane of the single crystal substrate.

In some preferred embodiments, SrTiO₃ (STO) single crystal substrate is used. STO substrate is cubic, by the virtue of which, (001), (010) and (100) are equivalent planes. In this sense, whichever substrate orientation of STO is used, the plane of piezoelectric thin film parallel to the plane (normal to the surface) of substrate will be (001).

Accordingly, in some embodiments, the present invention provides a piezoelectric thin film element comprising:
a) a piezoelectric thin film with formula (K,Na)NbO₃ and said film having (K+Na)/Nb ratio from about 0.64 to about 0.95; and
b) a cubic single crystal substrate having a (001), (010) or (100) crystallographic plane perpendicular to a surface;

wherein the piezoelectric thin film is adjacent to the surface of the single crystal substrate and the piezoelectric thin film is oriented such that its (001) crystallographic plane is parallel to the (001), (010) or (100) crystallographic plane of the single crystal substrate.

In some embodiments, y is less than 0.95. In other embodiments, y is less than or equal to 0.95. In other embodiments, 0.60≤y≤0.95, or 0.60≤y≤0.90, or 0.60≤y≤0.85, or 0.60≤y≤0.80, or 0.60≤y≤0.75.

In some embodiments, the piezoelectric thin film element comprises:
a) a piezoelectric thin film, the piezoelectric thin film with an empirical formula (K₁₋ₓNaₓ)_{y}NbO₃, wherein 0≤x≤1 and y≤0.95; and
b) a single crystal substrate having a (001), (010) or (100) crystallographic plane perpendicular to a surface;

wherein the piezoelectric thin film is adjacent to the surface of the single crystal substrate and the piezoelectric thin film is oriented such that its (001), (010) or (100) crystallographic plane is substantially parallel to either (001), (010) or (100) crystallographic plane of the single crystal substrate.

In some embodiments, the piezoelectric thin film has an empirical formula (K₁₋ₓNaₓ)_{y}NbO₃, wherein 0≤x≤1 and 0.64<y≤0.95. In other embodiments, the piezoelectric thin film has an empirical formula (K₁₋ₓNaₓ)_{y}NbO₃, wherein 0≤x≤1 and 0.64≤y≤0.95.

In some embodiments, the piezoelectric thin film element comprises:
a) a piezoelectric thin film with an empirical formula (K₁₋ₓNaₓ)_{y}NbO₃, wherein 0≤x≤1 and 0.64≤y≤0.95; and
b) a single crystal substrate having a (001), (010) or (100) crystallographic plane perpendicular to a surface;

wherein the piezoelectric thin film is adjacent to the surface of the single crystal substrate and the piezoelectric thin film is oriented such that its (001), (010) or (100) crystallographic plane is substantially parallel to either (001), (010) or (100) crystallographic plane of the single crystal substrate.

In some embodiments, the piezoelectric thin film element comprises:
a) a piezoelectric thin film with an empirical formula (K₁₋ₓNaₓ)_{y}NbO₃, wherein 0≤x≤1 and 0.64≤y≤0.95; and
b) a single crystal substrate having a (001), (010) or (100) crystallographic plane perpendicular to a surface;

wherein the piezoelectric thin film is adjacent to the surface of the single crystal substrate and the piezoelectric thin film is oriented such that its (001), (010) or (100) crystallographic plane is substantially parallel to the respective (001), (010) or (100) crystallographic plane of the single crystal substrate, or the (001) crystallographic plane of the single crystal substrate.

In some embodiments, the piezoelectric thin film element comprises:
a) a piezoelectric thin film with an empirical formula (K₁₋ₓNaₓ)_{y}NbO₃, wherein 0≤x≤1 and 0.64≤y≤0.95; and
b) a single crystal substrate having a (001), (010) or (100) crystallographic plane perpendicular to a surface;

wherein the piezoelectric thin film is adjacent to the surface of the single crystal substrate and the piezoelectric thin film is oriented such that its (001), (010) or (100) crystallographic plane is substantially parallel to the respective (001), (010) or (100) crystallographic plane of the single crystal substrate.

In some embodiments, the piezoelectric thin film element comprises:
a) a piezoelectric thin film with an empirical formula (K₁₋ₓNaₓ)_{y}NbO₃, wherein 0≤x≤1 and 0.64≤y≤0.95; and
b) a cubic single crystal substrate having a (001), (010) or (100) crystallographic plane perpendicular to a surface;

wherein the piezoelectric thin film is adjacent to the surface of the single crystal substrate and the piezoelectric thin film is oriented such that its (001) crystallographic plane is substantially parallel to the (001), (010) or (100) crystallographic plane of the single crystal substrate.

In some embodiments, the piezoelectric thin film element comprises:
a) a piezoelectric thin film with an empirical formula (K₁₋ₓNaₓ)_{y}NbO₃, wherein 0≤x≤1 and 0.64≤y≤0.95; and
b) a single crystal substrate having a (001), (010) or (100) crystallographic plane perpendicular to a surface;

wherein the piezoelectric thin film is adjacent to the surface of the single crystal substrate and the piezoelectric thin film is oriented such that its (001), (010) or (100) crystallographic plane is substantially parallel to the either (001), (010) or (100) crystallographic plane of the single crystal substrate;

wherein the piezoelectric thin film has columnar grains oriented in a respective [001], [010] or [100] direction; and

wherein the piezoelectric thin film comprises at least two adjacent NbO₂ planes in the antiphase boundary.

In an aspect, the present invention provides a piezoelectric thin film element comprising:
a) a piezoelectric thin film, the piezoelectric thin film with an empirical formula (K₁₋ₓNaₓ)_{y}NbO₃, wherein 0≤x≤1 and 0.64≤y≤0.95; and
b) a single crystal substrate having a (001), (010) or (100) crystallographic plane perpendicular to a surface;

wherein the piezoelectric thin film is adjacent to the surface of the single crystal substrate and the piezoelectric thin film is oriented such that its (001), (010) or (100) crystallographic plane is substantially parallel to either (001), (010) or (100) crystallographic plane of the single crystal substrate; and

wherein the piezoelectric thin film comprises at least two adjacent NbO₂ planes in an antiphase boundary, the at least two adjacent NbO₂ planes displaced from each other by about half a lattice length in either the (100), (010) or (100) crystallographic plane.

In some embodiments, the piezoelectric thin film element comprises:
a) a piezoelectric thin film with an empirical formula (K₁₋ₓNaₓ)_{y}NbO₃, wherein 0≤x≤1 and 0.64≤y≤0.95; and
b) a single crystal substrate having a (001) crystallographic plane perpendicular to a surface;

wherein the piezoelectric thin film is adjacent to the surface of the single crystal substrate and the piezoelectric thin film is oriented such that its (001) crystallographic plane is substantially parallel to the (001) crystallographic plane of the single crystal substrate; and

wherein the piezoelectric thin film comprises at least two adjacent NbO₂ planes in an antiphase boundary, the at least two adjacent NbO₂ planes displaced from each other by about half a lattice length in either the (100), (010) or (100) crystallographic plane.

In some embodiments, the piezoelectric thin film is oriented such that its (001) crystallographic plane is completely parallel to the (001) crystallographic plane of the single crystal substrate. In other embodiments, the piezoelectric thin film is oriented such that its (010) crystallographic plane is completely parallel to the (010) crystallographic plane of the single crystal substrate. In other embodiments, the piezoelectric thin film is oriented such that its (100) crystallographic plane is completely parallel to the (100) crystallographic plane of the single crystal substrate. In this regard, 100% of the piezoelectric thin film is oriented parallel to the single crystal substrate. In some embodiments, the piezoelectric thin film is oriented such that its (001) crystallographic plane is substantially parallel to the (001) crystallographic plane of the single crystal substrate. In some embodiments, the piezoelectric thin film is oriented such that its (010) crystallographic plane is substantially parallel to the (010) crystallographic plane of the single crystal substrate. In some embodiments, the piezoelectric thin film is oriented such that its (100) crystallographic plane is substantially parallel to the (100) crystallographic plane of the single crystal substrate. As used herein, the piezoelectric thin film being oriented substantially parallel to the single crystal substrate refers to at least 90%, at least 92%, at least 94%, at least 96%, at least 98%, or at least 99% of the piezoelectric thin film being oriented parallel to the single crystal substrate. Preferably, the piezoelectric thin film is oriented 100% parallel to the single crystal substrate.

In some embodiments, the piezoelectric thin film has columnar grains oriented in [001] direction. In some embodiments, the piezoelectric thin film has columnar grains oriented in [010] direction. In some embodiments, the piezoelectric thin film has columnar grains oriented in [100] direction.

In some embodiments, the piezoelectric thin film comprises at least two adjacent NbO₂ planes in the antiphase boundary. In some embodiments, the piezoelectric thin film comprises at least two adjacent NbO₂ planes in the antiphase boundary displaced from each other by about half a lattice length in a (001), (100) or (010) crystallographic plane. In this regard, the at least two NbO₂ planes are in contact with each other and are displaced from each other by about half a lattice length.

In some embodiments, the at least two adjacent NbO₂ planes in the antiphase boundary are displaced from each other by about 0.220 nm to about 0.260 nm in the (100) crystallographic plane. In this regard, the at least two NbO₂ planes are in contact with each other and are displaced from each other by about 0.220 nm to about 0.260 nm.

In some embodiments, the at least two adjacent NbO₂ planes in the antiphase boundary are displaced from each other by about 0.220 nm to about 0.260 nm in the (010) crystallographic plane. In this regard, the at least two NbO₂ planes are in contact with each other and are displaced from each other by about 0.220 nm to about 0.260 nm.

In some embodiments, the at least two adjacent NbO₂ planes in the antiphase boundary are displaced from each other by about 0.220 nm to about 0.260 nm in the (001) crystallographic plane. In this regard, the at least two NbO₂ planes are in contact with each other and are displaced from each other by about 0.220 nm to about 0.260 nm.

In some embodiments, the density of antiphase boundaries of the piezoelectric thin film is about 0.05 nm⁻¹ to about 0.30 nm⁻¹. In other embodiments, the density of antiphase boundaries of the piezoelectric thin film is about 0.10 nm⁻¹ to about 0.30 nm⁻¹, about 0.15 nm⁻¹ to about 0.30 nm⁻¹, or about 0.20 nm⁻¹ to about 0.30 nm⁻¹.

In some embodiments, the piezoelectric thin film element comprises:
a) a piezoelectric thin film with an empirical formula (K₁₋ₓNaₓ)_{y}NbO₃, wherein 0≤x≤1 and 0.64≤y≤0.95; and
b) a single crystal substrate having a (001) crystallographic plane perpendicular to a surface;

wherein the piezoelectric thin film is adjacent to the surface of the single crystal substrate and the piezoelectric thin film is oriented such that its (001) crystallographic plane is substantially parallel to the (001) crystallographic plane of the single crystal substrate;

wherein the piezoelectric thin film has columnar grains oriented in [001] direction; and

wherein the piezoelectric thin film comprises at least two adjacent NbO₂ planes in the antiphase boundary.

In some embodiments, the piezoelectric thin film has an effective longitudinal piezoelectric coefficient (d₃₃*) of more than about 1000 pm/V. In other embodiments, d₃₃* is about 1000 pm/V to about 2000 pm/V, or about 1200 pm/V to about 1700 pm/V at an applied voltage of about 60 kV/cm and a frequency of about 1 kHz.

In some embodiments, the piezoelectric thin film element comprises:
a) a piezoelectric thin film with an empirical formula (K₁₋ₓNaₓ)_{y}NbO₃, wherein 0≤x≤1 and 0.64≤y≤0.95; and
b) a single crystal substrate having a (001) crystallographic plane perpendicular to a surface;

wherein the piezoelectric thin film is adjacent to the surface of the single crystal substrate and the piezoelectric thin film is oriented such that its (001) crystallographic plane is substantially parallel to the (001) crystallographic plane of the single crystal substrate;

wherein the piezoelectric thin film has columnar grains oriented in [001] direction;

wherein the piezoelectric thin film comprises at least two adjacent NbO₂ planes in the antiphase boundary; and

the piezoelectric thin film has an effective longitudinal piezoelectric coefficient (d₃₃*) of about 1200 pm/V to about 1700 pm/V at an applied voltage of about 60 kV/cm and a frequency of about 1 kHz.

In some embodiments, the piezoelectric thin film has a columnar structure, the columnar structure having a width of about 3 nm to about 6 nm.

In some embodiments, the piezoelectric film has a thickness of about 100 nm to about 500 nm.

In some embodiments, the substrate is an optionally doped perovskite single crystal. For example, the perovskite can be doped with Nb. The doping can be of about 0.01% to 1% or preferably 0.5%.

The single crystal substrate can be a perovskite single crystal substrate. In this regard, the single crystal substrate can have a cubic structure. Alternatively, the cubic structure can evolve into tetragonal, orthorhombic or rhombohedral with lower symmetry, originating from thermal- or stress-induced lattice distortions.

In some embodiments, the substrate is a perovskite single crystal selected from SrTiO₃, LaAlO₃, DyScO₃, (La,Sr)(Al,Ti)O₃, Si, NdGaO₃, LiTaO₃, YAlO₃, LaₓSr₁₋ₓFeO₃, LaₓCa₁₋ₓFeO₃, LaₓSr₁₋ₓCoO₃, LaₓSr₁₋ₓMnO₃, LaNiO₃, and SrRuO₃.

Advantageously, the crystallographic planes of the piezoelectric thin film normal to the surface of the film are alignable with the planes of the substrate normal to its surface during its formation. The crystallographic planes of the piezoelectric thin film parallel to the surface of the film are free to form their own lattice spacing or interplanar distances.

In some embodiments, the piezoelectric thin film element further comprises a perovskite oxide layer sandwiched between the piezoelectric thin film and the substrate. The perovskite oxide layer can be the intervening structure as mentioned herein.

In some embodiments, the perovskite oxide layer is selected from LaₓSr₁₋ₓFeO₃, LaₓCa₁₋ₓFeO₃, LaₓSr₁₋ₓCoO₃, LaₓSr₁₋ₓMnO₃, LaNiO₃, and SrRuO₃.

In some embodiments, the perovskite oxide layer has a thickness of about 1 nm to about 300 nm.

In some embodiments, the piezoelectric thin film element further comprises an electrode layered on top of the piezoelectric thin film.

In some embodiments, the electrode is selected from Pt, Au, Ag, Cu, Cr, Al, LaₓSr₁₋ₓFeO₃, LaₓCa₁₋ₓFeO₃, LaₓSr₁₋ₓCoO₃, LaₓSr₁₋ₓMnO₃, LaNiO₃, and SrRuO₃.

The present invention also provides a piezoelectric device, comprising:
c) piezoelectric thin film element as disclosed herein; and
d) at least two electrodes in contact with the piezoelectric thin film element.

In some embodiments, the single crystal substrate in the piezoelectric thin film element is one of the at least two electrodes.

The present invention also provides a method of fabricating a piezoelectric thin film element, comprising:

forming a piezoelectric thin film on a single crystal substrate, the piezoelectric thin film having (K+Na)/Nb ratio from about 0.64 to about 0.95;

wherein the single crystal substrate has a (001), (010) or (100) crystallographic plane perpendicular to a surface; and

wherein the piezoelectric thin film is adjacent to the surface of the single crystal substrate and the piezoelectric thin film is oriented such that its (001), (010) or (100) crystallographic plane is substantially parallel to either (001), (010) or (100) crystallographic plane of the single crystal substrate.

The present invention also provides a method of fabricating a piezoelectric thin film element, comprising:

forming a piezoelectric thin film on a single crystal substrate, the piezoelectric thin film having (K+Na)/Nb ratio from about 0.64 to about 0.95;

wherein the single crystal substrate has a (001), (010) or (100) crystallographic plane perpendicular to a surface; and

wherein the piezoelectric thin film is adjacent to the surface of the single crystal substrate and the piezoelectric thin film is oriented such that its (001), (010) or (100) crystallographic plane is substantially parallel to either (001), (010) or (100) crystallographic plane of the single crystal substrate; and

wherein the piezoelectric thin film comprises at least two adjacent NbO₂ planes in an antiphase boundary, the at least two adjacent NbO₂ planes displaced from each other by about half a lattice length in either the (100), (010) or (100) crystallographic plane.

In some embodiments, the method of fabricating a piezoelectric thin film element, comprises:

forming a piezoelectric thin film with an empirical formula (K₁₋ₓNaₓ)_{y}NbO₃ on a single crystal substrate, wherein 0≤x≤1 and y≤0.95;

wherein the single crystal substrate has a (001), (010) or (100) crystallographic plane perpendicular to a surface; and

wherein the piezoelectric thin film is adjacent to the surface of the single crystal substrate and the piezoelectric thin film is oriented such that its (001), (010) or (100) crystallographic plane is substantially parallel to either (001), (010) or (100) crystallographic plane of the single crystal substrate; and

wherein the piezoelectric thin film comprises at least two adjacent NbO₂ planes in an antiphase boundary, the at least two adjacent NbO₂ planes displaced from each other by about half a lattice length in either the (100), (010) or (100) crystallographic plane.

In some embodiments, the method of fabricating a piezoelectric thin film element, comprises:

forming a piezoelectric thin film with an empirical formula (K₁₋ₓNaₓ)_{y}NbO₃ on a single crystal substrate, wherein 0≤x≤1 and 0.64≤y≤0.95;

wherein the single crystal substrate has a (001), (010) or (100) crystallographic plane perpendicular to a surface; and

wherein the piezoelectric thin film is adjacent to the surface of the single crystal substrate and the piezoelectric thin film is oriented such that its (001), (010) or (100) crystallographic plane is substantially parallel to either (001), (010) or (100) crystallographic plane of the single crystal substrate; and

wherein the piezoelectric thin film comprises at least two adjacent NbO₂ planes in an antiphase boundary, the at least two adjacent NbO₂ planes displaced from each other by about half a lattice length in either the (100), (010) or (100) crystallographic plane.

In some embodiments, the method of fabricating a piezoelectric thin film element, comprises:

forming a piezoelectric thin film with an empirical formula (K₁₋ₓNaₓ)_{y}NbO₃ on a single crystal substrate, wherein 0≤x≤1 and 0.64≤y≤0.95;

wherein the single crystal substrate has a (001), (010) or (100) crystallographic plane perpendicular to a surface; and

wherein the piezoelectric thin film is adjacent to the surface of the single crystal substrate and the piezoelectric thin film is oriented such that its (001), (010) or (100) crystallographic plane is substantially parallel to either (001), (010) or (100) crystallographic plane of the single crystal substrate;

wherein the piezoelectric thin film has columnar grains oriented in a respective [001], [010] or [100] direction; and

wherein the piezoelectric thin film comprises at least two adjacent NbO₂ planes in the antiphase boundary.

In some embodiments, the method of fabricating a piezoelectric thin film element, comprises:

forming a piezoelectric thin film with an empirical formula (K₁₋ₓNaₓ)_{y}NbO₃ on a single crystal substrate, wherein 0≤x≤1 and 0.64≤y≤0.95;

wherein the single crystal substrate has a (001) crystallographic plane perpendicular to a surface; and

wherein the piezoelectric thin film is adjacent to the surface of the single crystal substrate and the piezoelectric thin film is oriented such that its (001) crystallographic plane is substantially parallel to the (001) crystallographic plane of the single crystal substrate.

In some embodiments, the method of fabricating a piezoelectric thin film element, comprises:

forming a piezoelectric thin film with an empirical formula (K₁₋ₓNaₓ)_{y}NbO₃ on a single crystal substrate, wherein 0≤x≤1 and 0.64≤y≤0.95;

wherein the single crystal substrate has a (001) crystallographic plane perpendicular to a surface; and

wherein the piezoelectric thin film is adjacent to the surface of the single crystal substrate and the piezoelectric thin film is oriented such that its (001) crystallographic plane is substantially parallel to the (001) crystallographic plane of the single crystal substrate; and

wherein the piezoelectric thin film comprises at least two adjacent NbO₂ planes in an antiphase boundary, the at least two adjacent NbO₂ planes displaced from each other by about half a lattice length in either the (100), (010) or (100) crystallographic plane.

In some embodiments, the method of fabricating a piezoelectric thin film element, comprises:

forming a piezoelectric thin film with an empirical formula (K₁₋ₓNaₓ)_{y}NbO₃ on a single crystal substrate, wherein 0≤x≤1 and 0.64≤y≤0.95;

wherein the single crystal substrate has a (001) crystallographic plane perpendicular to a surface; and

wherein the piezoelectric thin film is adjacent to the surface of the single crystal substrate and the piezoelectric thin film is oriented such that its (001) crystallographic plane is substantially parallel to the (001) crystallographic plane of the single crystal substrate;

wherein the piezoelectric thin film has columnar grains oriented in [001] direction; and

wherein the piezoelectric thin film comprises at least two adjacent NbO₂ planes in the antiphase boundary.

In some embodiments, the step of forming the piezoelectric thin film comprises depositing the piezoelectric thin film using sputtering.

In some embodiments, the step of forming the piezoelectric thin film comprises sputtering at a substrate temperature of about 680° C. and a discharge power of about 120 W.

In some embodiments, the sputtering is performed for at least 2 h. The sputtering can be performed for at least 1.5 h, at least 3 h, or at least 4 h.

In some embodiments, the sputtering is performed in an argon-oxygen ratio (Ar/O) of about 50/15.

In some embodiments, the sputtering is performed under a total pressure of about 3.5×10⁻³ mtorr.

In some embodiments, the sputtering angle, substrate-target distance, argon-oxygen ratio and/or deposition temperature are controlled such that (K+Na)/Nb ratio is from about 0.64 to about 0.95.

In some embodiments, the method further comprises a step of cutting and polishing a surface of the single crystal substrate having a (001), (010) or (100) crystallographic plane perpendicular to the surface before the sputtering.

In some embodiments, the piezoelectric thin film can be grown on a water-soluble single crystal substrate. In some embodiments, the piezoelectric thin film can be grown on an organic single crystal substrate. Accordingly, and in such cases, a piezoelectric thin film can be obtained by removing the substrate via a post-deposition step.

### EXAMPLES

Examples of the present invention will now be discussed below however the scope of the invention is not limited just to these examples.

### Example 1

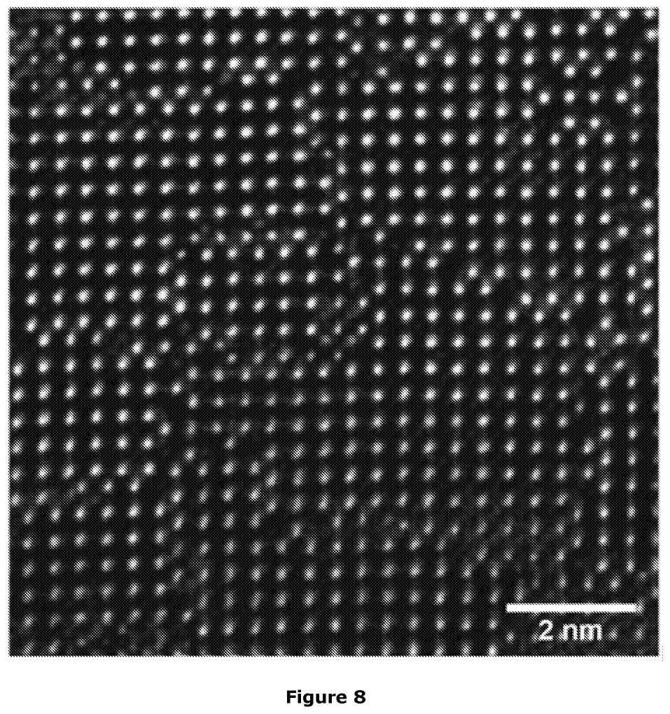

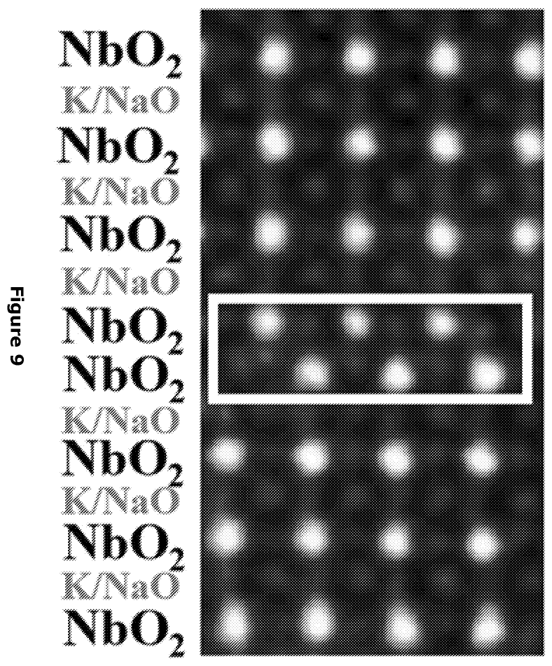

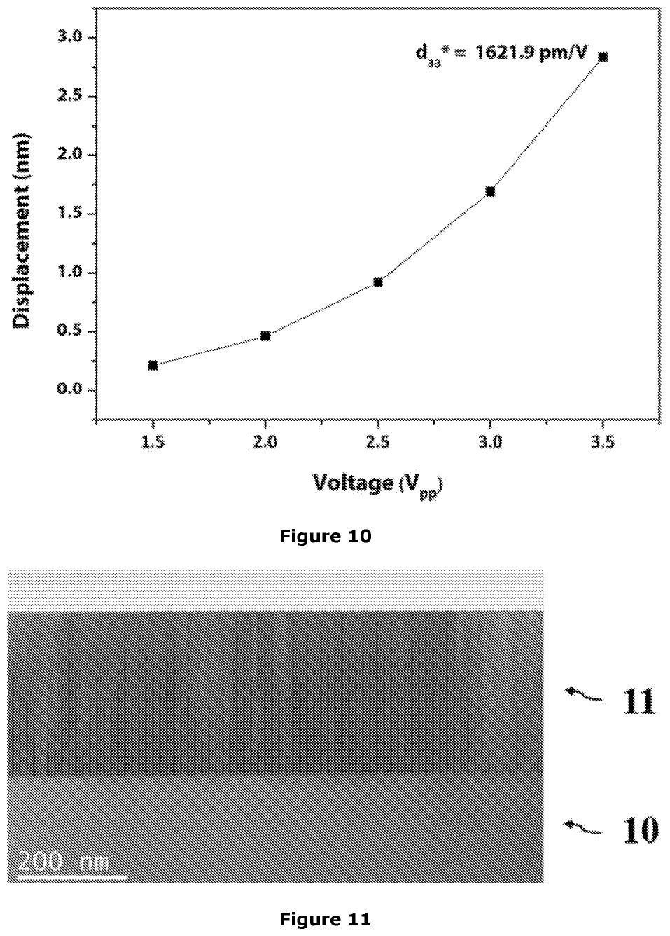

Piezoelectric thin film with formula (K,Na)NbO₃ where the content ratio of K is 30% on the assumption that the total content of K and Na is 100%, wherein (K+Na)/Nb ratio is 0.64, and which is grown on a (001) oriented 0.5% Nb doped SrTiO₃ single crystal substrate and has a columnar structure with pillar-like grains extending from the substrate surface perpendicular to the horizontal of the film (see FIG. 7). Such columnar grains have a width of not more than 5-6 nm on average and the total thickness of film is 300 nm (see FIG. 8). These grains are separated from each other by antiphase boundaries or antiphase grain boundaries, density of which is measured to be 0.23 nm⁻¹. This specific antiphase boundary is formed by two adjacent NbO₂ planes where one of the two NbO₂ planes is displaced by a distance of ½<100> a or ½<010> a where a is the horizontal lattice parameter and <100> and <010> are families of two horizontal crystallographic directions (see FIG. 9). When a voltage of 58.3 kV/cm applied at 1 kHz, the film shows an effective longitudinal piezoelectric coefficient d₃₃* of 1621.9 pm/V (See FIG. 10). Such piezoelectric thin film is highly suitable for stroke based applications such as microblowers, micropumps, microinjectors, switches.

### Example 2

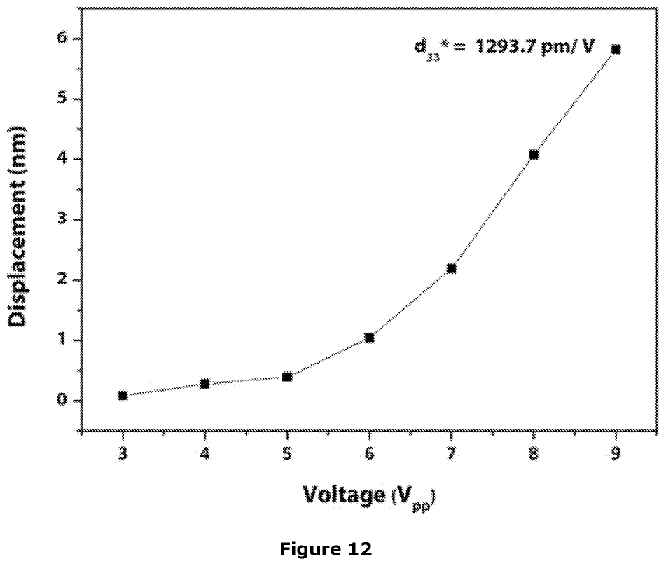

The piezoelectric thin film with formula (K,Na)NbO₃ where the content ratio of K is 30% on the assumption that the total content of K and Na is 100%, wherein (K+Na)/Nb ratio is 0.92, and which is grown on a (001) oriented 0.5% Nb doped SrTiO₃ single crystal substrate has a similar columnar structure as Example 1 with pillar like grains having average width of 10 nm (see FIG. 11). (K+Na)/Nb ratio in this film is 0.92 compared to 0.64 in the film mentioned in Example 1. This piezoelectric thin film shows a d₃₃* of 1293.7 pm/V at a driving voltage of 75 kV/cm measured at 1 kHz (FIG. 12).

Scanning transmission electron micrographs shown here were taken using a JEOL ARM200F atomic resolution electron microscope equipped with cold field emission gun and an ASCOR 5th order aberration corrector. Chemical compositions of thin film were measured using Zeiss Supra 40VP scanning electron microscope fitted with Oxford Instruments energy dispersive spectrometer operating at 20.0 kV. Voltage dependent displacement of piezoelectric thin films was measured using an OFV-3001-SF6 PolyTech GmbH (Germany) scanning laser vibrometer. Au electrodes with diameter of 200 μm were sputtered on the thin films followed with baking at 200° C. for 15 mins. The bottom electrode was exposed by depositing Au film on a small patch at one corner of the substrate prior to which the film was scratched using a diamond knife. The laser was scanned on the electrodes using a circular profile while the electrodes were excited with AC voltage. Antiphase boundary density is estimated by measuring the number of boundaries per unit length of the crystal lattice. 5 line scans were made from random locations on a 25 nm by 25 nm STEM micrograph and the number of boundaries crossing the 25 nm long scans were counted. Then the average number of APBs intersecting the lines were divided by the length of line scan i.e. 25 nm.

It will be appreciated that many further modifications and permutations of various aspects of the described embodiments are possible, such as change in substrate and A-site element doping. Accordingly, the described aspects are intended to embrace all such alterations, modifications, and variations that fall within the spirit and scope of the appended claims.

Throughout this specification and the claims which follow, unless the context requires otherwise, the word “comprise”, and variations such as “comprises” and “comprising”, will be understood to imply the inclusion of a stated integer or step or group of integers or steps but not the exclusion of any other integer or step or group of integers or steps.

The reference in this specification to any prior publication (or information derived from it), or to any matter which is known, is not, and should not be taken as an acknowledgment or admission or any form of suggestion that that prior publication (or information derived from it) or known matter forms part of the common general knowledge in the field of endeavor to which this specification relates.

1. A piezoelectric thin film element comprising:
a) a piezoelectric thin film with an empirical formula (K₁₋ₓNaₓ)_{y}NbO₃, wherein 0≤x≤1 and 0.64≤y≤0.95; and
b) a single crystal substrate having a (001), (010) or (100) crystallographic plane perpendicular to a surface;
wherein the piezoelectric thin film is adjacent to the surface of the single crystal substrate and the piezoelectric thin film is oriented such that its (001) crystallographic plane is substantially parallel to either (001), (010) or (100) crystallographic plane of the single crystal substrate; and
wherein the piezoelectric thin film comprises at least two adjacent NbO₂ planes in an antiphase boundary, the at least two adjacent NbO₂ planes displaced from each other by about half a lattice length in either the (100), (010) or (100) crystallographic plane.

2. The piezoelectric thin film element according to claim 1, having columnar grains oriented in a respective [001], [010] or [100] direction.

3. The piezoelectric thin film element according to claim 1, wherein the at least two adjacent NbO₂ planes in the antiphase boundary are displaced from each other by about 0.220 nm to about 0.260 nm in either (001), (010) or (100) crystallographic plane.

4. The piezoelectric thin film element according to claim 1, wherein a density of antiphase boundaries of the piezoelectric thin film is about 0.05 nm−1 to about 0.30 nm−1.

5. The piezoelectric thin film element according to claim 1, wherein the piezoelectric thin film has an effective longitudinal piezoelectric coefficient (d₃₃*) of about 1200 pm/V to about 1700 pm/V at an applied voltage of about 60 kV/cm and a frequency of about 1 kHz.

6. The piezoelectric thin film element according to claim 1, wherein the piezoelectric thin film has a columnar structure, the columnar grains having a width of about 3 nm to about 6 nm.

7. The piezoelectric thin film element according to claim 1, wherein the piezoelectric thin film has a thickness of about 100 nm to about 500 nm.

8. The piezoelectric thin film element according to claim 1, wherein the substrate is an optionally doped perovskite single crystal.

9. The piezoelectric thin film element according to claim 1, wherein the substrate is a perovskite single crystal selected from SrTiO₃, LaAlO₃, DyScO₃, (La,Sr)(Al,Ti)O₃, Si, NdGaO₃, LiTaO₃, YAlO₃, LaₓSr₁₋ₓFeO₃, LaₓCa₁₋ₓFeO₃, LaₓSr₁₋ₓCoO₃, LaₓSr₁₋ₓMnO₃, LaNiO₃, and SrRuO₃.

10. The piezoelectric thin film element according to claim 1, wherein the piezoelectric thin film further comprises a perovskite oxide layer sandwiched between the piezoelectric thin film and the substrate, wherein the perovskite oxide layer is selected from LaₓSr₁₋ₓFeO₃, LaₓCa₁₋ₓFeO₃, LaₓSr₁₋ₓCoO₃, LaₓSr₁₋ₓMnO₃, LaNiO₃, and SrRuO₃.

11. (canceled)

12. The piezoelectric thin film element according to claim 10, wherein the perovskite oxide layer has a thickness of about 1 nm to about 300 nm.

13. The piezoelectric thin film element according to claim 1, further comprising an electrode layered on top of the piezoelectric thin film.

14. The piezoelectric thin film element according to claim 13, the electrode is selected from Pt, Au, Ag, Cu, Cr, Al, LaₓSr₁₋ₓFeO₃, LaₓCa₁₋ₓFeO₃, LaₓSr₁₋ₓCoO₃, LaₓSr₁₋ₓMnO₃, LaNiO₃, and SrRuO₃.

15. A piezoelectric device, comprising
a) piezoelectric thin film element according to claim 1; and
b) at least two electrodes in contact with the piezoelectric thin film.

16. The piezoelectric device according to claim 15, wherein the single crystal substrate in the piezoelectric thin film is one of the at least two electrodes.

17. A method of fabricating a piezoelectric thin film element, comprising:
forming a piezoelectric thin film with an empirical formula (K1-xNax)yNbO3 on a single crystal substrate, wherein 0≤x≤1 and 0.64≤y≤0.95;
wherein the single crystal substrate has a (001), (010) or (100) crystallographic plane perpendicular to a surface;
wherein the piezoelectric thin film is adjacent to the surface of the single crystal substrate and the piezoelectric thin film is oriented such that its (001), (010) or (100) crystallographic plane is substantially parallel to the either (001), (010) or (100) crystallographic plane of the single crystal substrate; and
wherein the piezoelectric thin film comprises at least two adjacent NbO2 planes in an antiphase boundary, the at least two adjacent NbO2 planes displaced from each other by about half a lattice length in either the (100), (010) or (100) crystallographic plane.

18. The method according to claim 17, wherein the step of forming the piezoelectric thin film comprises depositing the piezoelectric thin film using sputtering.

19. The method according to claim 17, wherein the step of forming the piezoelectric thin film comprises sputtering performed at least one of the following conditions:
a) at a substrate temperature of about 680° C. and a discharge power of about 120 W;
b) for at least 2 h;
c) in an argon-oxygen ratio (Ar/O) of about 50/15; and
d) under a total pressure of about 3.5×10⁻³ mtorr.

20-22. (canceled)

23. The method according to claim 18, wherein the sputtering angle, substrate-target distance, argon-oxygen ratio and/or deposition temperature are controlled such that (K+Na)/Nb ratio is from about 0.64 to about 0.95.

24. The method according to claim 17, the method further comprises a step of cutting and polishing a surface of the single crystal substrate having a (001), (010) or (100) crystallographic plane perpendicular to the surface before the sputtering.
